(19) United States
(12) Patent Application Publication
(10) Pub. No.: US 2016/0072001 A1
(43) Pub. Date: Mar. 10, 2016

(54) METHOD FOR FABRICATING CRYSTALLINE PHOTOVOLTAIC CELLS

(71) Applicant: IMEC VZW, Leuven (BE)

(72) Inventors: MARIA RECAMAN PAYO, Leuven (BE); Filip Duerinckx, Kessel-Lo (BE); Monica Aleman, Etterbeek (BE)

(21) Appl. No.: 14/839,785

(22) Filed: Aug. 28, 2015

(30) Foreign Application Priority Data
Sep. 4, 2014 (EP) 14183484.6

(51) Int. Cl. H01L 31/18; H01L 31/028; H01L 31/036; H01L 31/04

(52) U.S. Cl. CPC H01L 31/1804; H01L 31/04; H01L 31/028; H01L 31/036

(57) ABSTRACT

A method for fabricating a crystalline semiconductor photovoltaic cell is disclosed. In one aspect, the method includes depositing a dielectric layer at first predetermined locations on a surface of a semiconductor substrate. The method further includes growing a doped epitaxial layer at second predetermined locations on a surface of the semiconductor substrate, the second predetermined locations being different from and non-overlapping with the first predetermined locations. The method further includes maintaining the dielectric layer as a surface passivation layer in the photovoltaic cell. The method also includes forming an emitter region, a back surface field region or a front surface field region of the photovoltaic cell from the doped epitaxial layer.

### RELATED APPLICATIONS

This application claims priority to European Application No. EP 14183484.6 filed on Sep. 4, 2014, entitled “METHOD FOR FABRICATING CRYSTALLINE PHOTOVOLTAIC CELLS,” which is incorporated herein by reference in its entirety.

### BACKGROUND

1. Field

The disclosed technology relates to semiconductor technology, and particularly to methods for fabricating crystalline photovoltaic cells, such as crystalline silicon photovoltaic cells.

2. Description of the Related Technology

Epitaxial growth of highly doped regions is a promising technique for the creation of emitter regions, back surface field (BSF) regions, and front surface field (FSF) regions of silicon photovoltaic cells. High throughput for epitaxial growth may be obtained by using a low pressure chemical vapor deposition (LPCVD) system wherein the silicon substrates or wafers are loaded in batch-type substrate boats. In such high throughput systems, all substrate surfaces are exposed to the precursors used during epitaxial growth. Epitaxial growth occurs on all silicon surfaces exposed to the precursors. Therefore a masking step prior to epitaxy or a patterning step after epitaxy is needed if a local epitaxial layer pattern is needed or if an epitaxial layer is to be provided on a single substrate surface only.

In addition, surface passivation of the silicon surfaces not subjected to epitaxial growth is desired. Classical thermal oxidation (dry or wet) results in a high quality surface passivation but requires a high thermal budget, and all exposed surfaces, including the epitaxial layer surfaces, are oxidized. Oxidation of the epitaxial layer surfaces may be undesirable if, for example, a passivation layer is needed on the epitaxial layer surfaces. Therefore either a masking step or a patterning step is needed in case of thermal oxidation. Alternatively a locally applied passivation layer may be used for passivating the silicon surfaces not subjected to epitaxial growth, but such layers often require additional process steps (such as annealing) to obtain a good surface passivation.

### SUMMARY OF CERTAIN INVENTIVE ASPECTS

The disclosed technology includes a method for fabricating crystalline photovoltaic cells, such as crystalline silicon photovoltaic cells, wherein the number of process steps and/or the thermal budget is reduced as compared to known fabrication processes.

The disclosed technology includes a method for fabricating crystalline photovoltaic cells, such as crystalline silicon photovoltaic cells, wherein the number of process steps performed at a temperature exceeding 600° C. is reduced as compared to known fabrication processes.

The disclosed technology includes a method for fabricating crystalline photovoltaic cells, such as crystalline silicon photovoltaic cells, with an improved performance as compared to similar cells fabricated using known fabrication processes.

One aspect is a method for fabricating a crystalline semiconductor photovoltaic cell. The method includes depositing a dielectric layer at first predetermined locations on a surface of a semiconductor substrate. The method includes growing a doped epitaxial layer at second predetermined locations on a surface of the semiconductor substrate, the second predetermined locations being different from and non-overlapping with the first predetermined locations. The dielectric layer remains on the surface of the semiconductor substrate during the fabrication of the photovoltaic cell. The dielectric layer is maintained as a surface passivation layer of the photovoltaic cell.

In an embodiment, a surface passivation quality of the dielectric layer is improved as a result of the epitaxial layer growth. For example, the surface passivation quality of the dielectric layer after epitaxial layer growth is better than the surface passivation quality of the as-deposited dielectric layer. An improved surface passivation quality results in a reduced surface recombination velocity.

In an embodiment, the dielectric layer is deposited at a temperature lower than 500° C. In an embodiment, depositing the dielectric layer at the first predetermined locations includes depositing the dielectric layer by chemical vapor deposition (CVD), atomic layer deposition (ALD), pyrolytic coating, spin coating, spray coating or dip coating. In an embodiment, the dielectric layer includes silicon oxide, silicon nitride, silicon carbide, oxynitride or titanium oxide. In an embodiment, the dielectric layer is a non-doped dielectric layer.

In an embodiment, growing the doped epitaxial layer includes growing doped epitaxial layer at a temperature in the range between 600° C. and 1000° C. In an embodiment, the step of growing the doped epitaxial layer may be the only step in the photovoltaic cell fabrication process that is done at a temperature higher than 600° C. However, the disclosed technology is not limited thereto and other steps in the photovoltaic cell fabrication process may be done at a temperature exceeding 600° C., such as a diffusion step for forming a front surface field (FSF). In an embodiment, the thickness of the doped epitaxial layer may be in the range between 10 nm and 5 μm, the disclosed technology not being limited thereto.

In an embodiment, the doped epitaxial layer forms an emitter region, a back surface field region and/or a front surface field of the photovoltaic cell.

In an embodiment, depositing the dielectric layer at the first predetermined locations includes depositing the dielectric layer at the first predetermined locations and at the second predetermined locations, followed by removing the dielectric layer from the second predetermined locations. In other embodiments, depositing the dielectric layer at the first predetermined locations may comprise depositing the dielectric layer only at the first predetermined locations.

In an embodiment, the first predetermined locations and the second predetermined locations are present on a same surface of the semiconductor substrate. In an embodiment, the first predetermined locations and the second predetermined locations are present on opposite surfaces of the semiconductor substrate. In an embodiment the first predetermined locations are present on both surfaces of the semiconductor substrate. In an embodiment, the second predetermined locations are present on both surfaces of the semiconductor substrate.

In an embodiment, growing the doped epitaxial layer at the second predetermined locations includes exposing both semiconductor substrate surfaces to a precursor used during epitaxial growth. One advantage of exposing both semiconductor substrate surfaces to a precursor is high throughput.

One advantage of the disclosed technology is that highly doped regions and good surface passivation layers may be formed simultaneously at different locations on a surface, or on opposite surfaces of a semiconductor substrate, with a minimal thermal budget (for example, requiring only a single high temperature step) and without the need for additional post-processing steps such as additional annealing steps for dopant activation or additional treatments (such as forming gas annealing) for improving the surface passivation quality. In the context of the disclosed technology, a high temperature step is a process step performed at a temperature of 600° C. or higher.

When fabricating crystalline photovoltaic cells, such as crystalline silicon photovoltaic cells, one advantage of the disclosed technology is the simultaneous creation of emitter regions and good surface passivation layers at different locations, or the simultaneous creation of back surface field regions and good surface passivation layers at different locations.

One advantage of the disclosed technology is fewer process steps to fabricate crystalline photovoltaic cells, as well as lower photovoltaic cell processing costs than known methods.

One advantage of the disclosed technology is improved surface passivation of the non-epitaxial surfaces and thus to an improved photovoltaic cell efficiency as compared to prior art methods.

One advantage of the disclosed technology is it allows fabricating photovoltaic cells with a lower thermal budget as compared to known methods. A lower thermal budget leads to a reduced influence on doping profiles already present, with a reduced dopant redistribution. Further, a lower thermal budget may reduce the risk of degradation of the substrate by reducing the risk of reduction of the minority carrier lifetime of the substrate.

In the context of the disclosed technology, the thermal budget of a process step is the total amount of thermal energy transferred to the substrate during the process step, such as a high temperature step. The thermal budget is proportional to the temperature and the duration of the process step.

Certain objects and advantages of various inventive aspects have been described herein above. Of course, it is to be understood that not necessarily all such objects or advantages may be achieved in accordance with any particular embodiment of the disclosure. Thus, for example, those skilled in the art will recognize that the disclosure may be embodied or carried out in a manner that achieves or optimizes one advantage or group of advantages as taught herein without necessarily achieving other objects or advantages as may be taught or suggested herein. Further, it is understood that this summary is merely an example and is not intended to limit the scope of the disclosure. The disclosure, both as to organization and method of operation, together with features and advantages thereof, may best be understood by reference to the following detailed description when read in conjunction with the accompanying drawings.

### BRIEF DESCRIPTION OF THE DRAWINGS

FIG. 1 is a cross sectional view of an n-type rear junction photovoltaic cell fabricated in an embodiment of the disclosed technology.

FIG. 2 is a flowchart illustrating an embodiment of intermediate process steps for fabricating the n-type rear junction photovoltaic cell of FIG. 1 in an embodiment of the disclosed technology.

FIG. 3 is a cross sectional view of a p-type passivated emitter and rear contact (PERC) cell fabricated in an embodiment of the disclosed technology.

FIG. 4 is a flowchart illustrating an embodiment of intermediate process steps for fabricating the p-type PERC cell of FIG. 3 in an embodiment of the disclosed technology.

FIG. 5 is a flowchart illustrating an embodiment of a method for for fabricating a crystalline semiconductor photovoltaic cell in an embodiment of the disclosed technology.

Any reference signs in the claims shall not be construed as limiting the scope of the disclosed technology.

In the different drawings, the same reference signs refer to the same or analogous elements.

### DETAILED DESCRIPTION OF CERTAIN INVENTIVE ASPECTS

In the following detailed description, numerous specific details are set forth in order to provide a thorough understanding of the disclosure and how it may be practiced in particular embodiments. However, it will be understood that the disclosed technology may be practiced without these specific details. In other instances, well-known methods, procedures and techniques have not been described in detail, so as not to obscure the disclosed technology.

The disclosed technology will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

In the context of the disclosed technology, the front surface or front side of a photovoltaic cell is the surface or side adapted for being oriented towards a light source and thus for receiving illumination. In case of bifacial photovoltaic cells, both surfaces are adapted to receive impinging light. In such case, the front surface or front side is the surface or side adapted for receiving the largest fraction of the light or illumination. The back surface, back side, rear surface or rear side of a photovoltaic cell is the surface or side opposite to the front surface. The front side of a substrate used to form a photovoltaic cell is the side of the substrate corresponding to the front side of the photovoltaic cell, while the rear side or back side of the substrate corresponds to the back side of the photovoltaic cell.

A method according to the disclosed technology forms a good surface passivation layer at first predetermined locations on a surface of a semiconductor substrate and deposits an epitaxial layer at second predetermined locations on a surface of the semiconductor substrate, the second predetermined locations being different from the first predetermined locations, wherein the method only requires a single high temperature step, being the epitaxial layer deposition step. The first predetermined locations and the second predetermined locations are non-overlapping.

A method according to the disclosed technology may be used in a fabrication process for crystalline photovoltaic cells. The method includes depositing a dielectric layer at first predetermined locations on a surface of a semiconductor substrate. The method next includes growing a doped epitaxial layer at second predetermined locations on a surface of the semiconductor substrate, the second predetermined locations being different from and non-overlapping with the first predetermined locations. The dielectric layer is maintained as a surface passivation layer in the photovoltaic cell. The dielectric layer remains on the surface of the semiconductor substrate during further fabrication of the photovoltaic cell.

In a method of the disclosed technology, the doped epitaxial layer may contain the same semiconductor material as the semiconductor substrate. For example, in embodiments of the disclosed technology the semiconductor substrate and the epitaxial layer may be crystalline silicon layers. However, the disclosed technology is not limited thereto: other semiconductor materials may be used and the epitaxial layer may contain a semiconductor material different from the material of the semiconductor substrate.

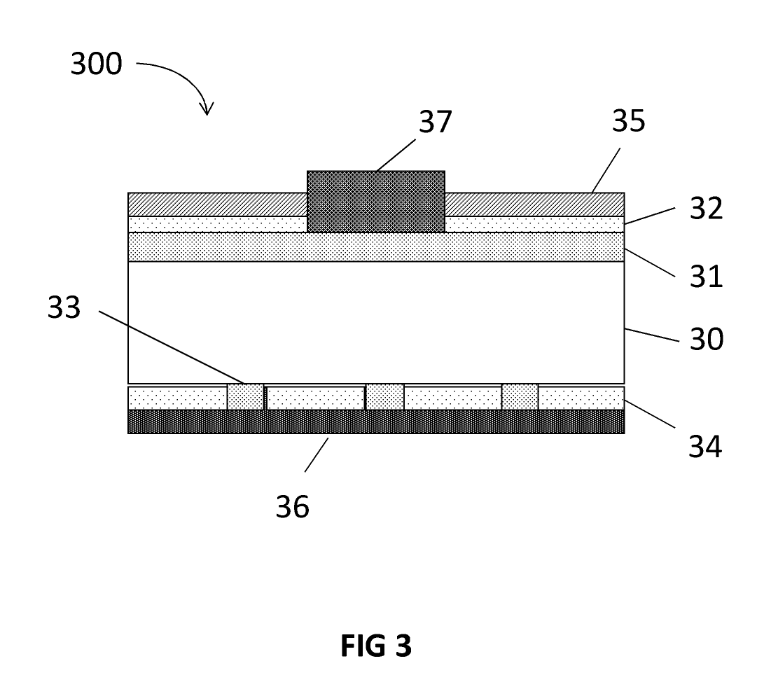

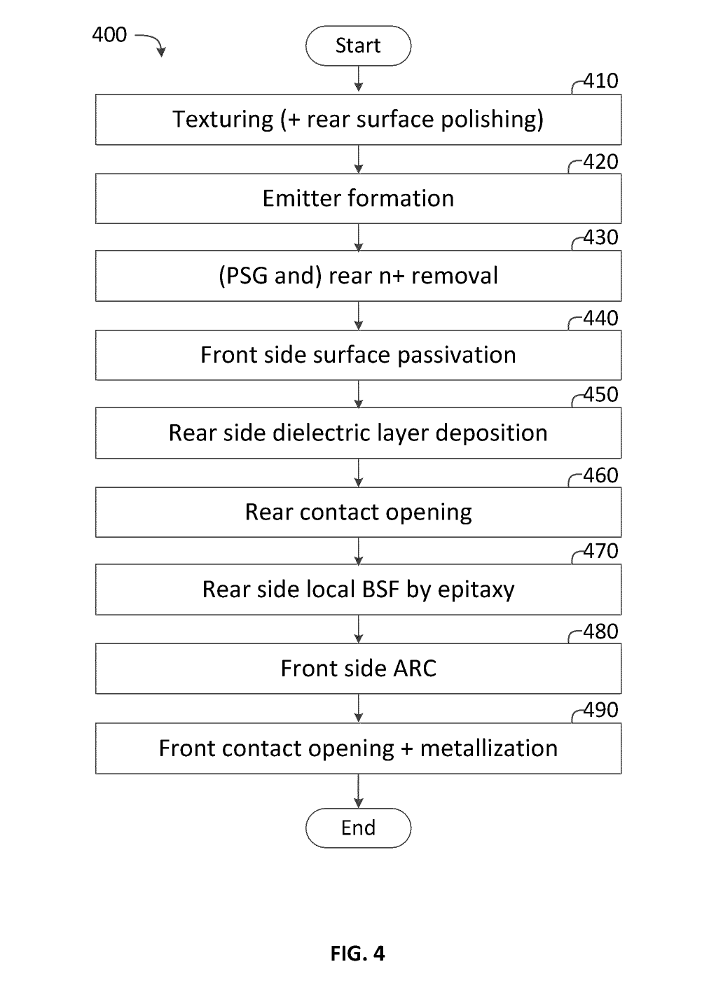

In some embodiments the first predetermined locations and the second predetermined locations may be adjacent to each other on a same substrate surface. An example of such an embodiment is further illustrated in FIG. 3 and FIG. 4. This example shows a fabrication process of a p-type PERC cell wherein the second predetermined locations correspond to local Back Surface Field regions at the rear side of the cell and wherein the first predetermined locations correspond to passivated regions at the rear side of the cell, at locations complementary to the Back Surface Field regions. This is only an example, and the disclosed technology is not limited thereto.

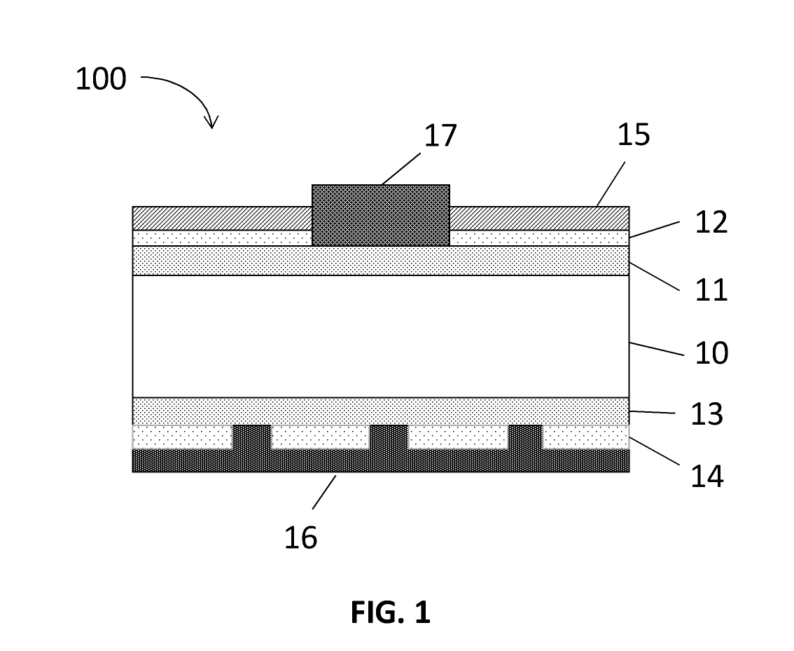

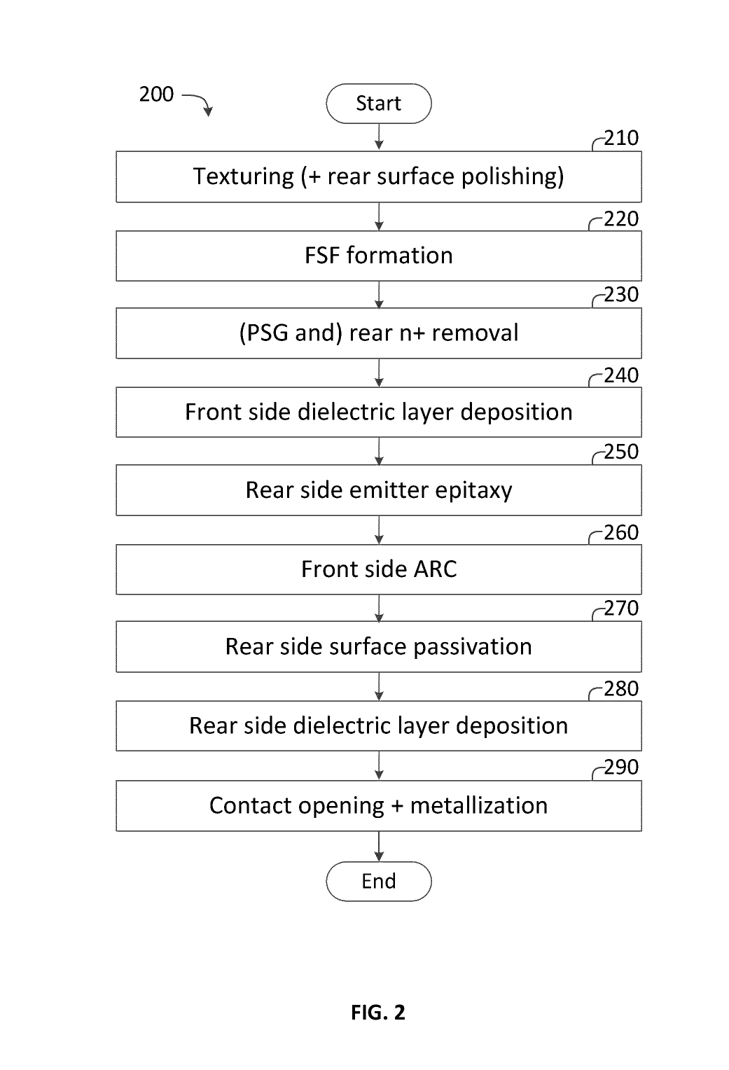

In some embodiments the first predetermined locations and the second predetermined locations may be on opposite surfaces of the substrate. An example of such an embodiment is further illustrated in FIG. 1 and FIG. 2. This example shows a fabrication process for an n-type rear junction photovoltaic cell wherein the first predetermined locations correspond to the front side of the cell and wherein the second predetermined locations correspond to rear side of the cell. This is only an example, and the disclosed technology is not limited thereto.

In some embodiments the first predetermined locations may be present at both substrate surfaces. An example is a fabrication process for a p-type PERC cell (FIG. 3) wherein the second predetermined locations correspond to a local back surface field region at the rear side of the cell and wherein the first predetermined locations correspond to passivated regions at the rear side of the cell, complementary to the back surface field regions and to the front side of the cell. This is only an example, and the disclosed technology is not limited thereto.

In some embodiments the second predetermined locations may be present at both substrate surfaces. An example of such an embodiment is a fabrication process for an n-type interdigitated back contact cell wherein the second predetermined locations correspond to the front side of the cell (front surface field) and to local back surface regions at the rear side of the cell, and wherein the first predetermined locations correspond to passivated regions at the rear side of the cell, complementary to the back surface field regions. This is only an example, and the disclosed technology is not limited thereto.

Depositing the dielectric layer at the first predetermined locations may for example be done by CVD (chemical vapor deposition), such as APCVD (atmospheric pressure CVD), PECVD (plasma enhanced CVD) or LPCVD (low pressure CVD), by ALD (atomic layer deposition), pyrolytic coating, spin coating, spray coating or dip coating. The dielectric layer may for example comprise or consist of SiOₓ, SiNₓ, SiCₓ, SiOₓN_{y} or TiOₓ, the disclosed technology not being limited thereto.

The doped epitaxial layer may be an emitter region, a back surface field region or a front surface field region of the photovoltaic cell.

In embodiments of the disclosed technology the epitaxial layer and the dielectric layer may be provided on a same surface of the semiconductor substrate. In such embodiments the step of growing the doped epitaxial layer is a selective epitaxial growth step wherein the dielectric layer functions as a masking layer for the epitaxial growth and wherein the epitaxial layer is grown at exposed locations on the surface of the semiconductor substrate. When in such embodiments the epitaxial growth is done in a reactor wherein both substrate surfaces are exposed to the precursors used for epitaxial growth, the surface of the substrate opposite to the surface where the dielectric layer and the epitaxial layer are provided may be masked, e.g. covered by a masking layer such as a dielectric layer, for preventing epitaxial growth on that surface.

In embodiments of the disclosed technology the epitaxial layer and the surface passivation layer may be provided on opposite surfaces of the semiconductor substrate. When in such embodiments the epitaxial growth is done in a reactor wherein both substrate surfaces are exposed to the precursors used for epitaxial growth, the dielectric layer on a surface functions as a masking layer for the epitaxial growth on that surface.

The surface passivation quality of the deposited dielectric layer, for example PECVD or APCVD silicon oxide layer, is substantially improved during the epitaxial growth step. For example, an experiment was done with a two-side textured n-type silicon test wafer. At both sides of the wafer a front surface field region with a sheet resistance of 175 Ohm per square was formed, and a PECVD silicon oxide layer was deposited on both front and rear wafer surfaces. On this test wafer an effective lifetime of 76 microseconds was measured. Next, the test wafer was subjected to a temperature profile (thermal budget) corresponding to epitaxial growth at 950° C., as would be used in a photovoltaic cell fabrication process for forming an emitter region. This resulted in an effective lifetime of 1.78 milliseconds. This substantial increase in effective lifetime can be attributed to a substantial increase of the surface passivation quality of the dielectric layer.

The epitaxial growth is typically done at a temperature in the range between 600° C. and 1000° C., for example between 800° C. and 950° C., with a growth rate in the range between 5 nm/min and 1000 nm/min, for example between 25 nm/min and 200 nm/min. The epitaxial layer thickness may be in the range between 10 nm and 5 μm, for example between 50 nm and 3 μm, the disclosed technology not being limited thereto. Examples of precursors that may be used during epitaxial growth are SiH₄, DCS (dichlorosilane), TCS (trichlorosilane), H₂ and HCl for (selective) silicon growth and AsH₃, PH₃, BCl₃, B₂H₆ for doping the epitaxial layer. However, the disclosed technology is not limited thereto and other suitable precursors known to a person skilled in the art may be used. For example, also higher-order silanes (such as disilane or neopentasilane) or organic precursors (such as triethoxysilane or tetramethylorthosilicate) may be used. The use of such precursors would allow a process that can be performed at low temperature (such as a temperature not exceeding 600° C.).

One advantage of a method of the disclosed technology that only a single high temperature step (such as epitaxy) is needed to create a good surface passivation layer at first predetermined locations and a doped layer at second predetermined locations.

An example of a silicon photovoltaic cell 100 that may be fabricated using a method of the disclosed technology is schematically shown in FIG. 1. The photovoltaic cell 100 shown in FIG. 1 is an n-type rear junction cell. It comprises an n-type silicon substrate 10 as a base region, and a blanket p⁺ doped emitter region 13 on the rear surface of the substrate 10. At the front surface a Front Surface Field (FSF) 11 is present for shielding minority carriers from the surface. This FSF requires a good front side passivation layer 12 to minimize surface recombination in this area. The cell further comprises at the front side an antireflection coating 15 and a front side contact 17. At the rear side a rear side dielectric layer or dielectric layer stack 14 is present, as well as a rear side contact 16. The rear side dielectric layer 14 may be a single layer or it may be a stack of at least two layers. The rear side dielectric layer 14 may be a stack comprising a surface passivation layer and at least one additional rear side dielectric layer covering the surface passivation layer, the at least one additional rear side dielectric layer being provided for improving rear side reflection and for preventing metal spiking. The photovoltaic cell 100 is shown in FIG. 1 with a non-textured front surface, but in embodiments the front surface may be textured.

An example of a method for fabricating the photovoltaic cell of FIG. 1 in accordance with a method 200 of the disclosed technology is schematically shown in FIG. 2.

In block 210 method 200 textures the front surface of a silicon substrate 10, for example, by etching in a KOH solution, a NaOH solution, a TMAH solution, a HF/HNO₃/CH₃COOH solution or by plasma texturing. The texturing may be a single side texturing step, wherein the rear side may be masked during texturing, or it may be a double side texturing step. In the latter case the texturing may be followed by a rear surface polishing step. In the example described here, the silicon substrate 10 is an n-type crystalline silicon substrate, for example with a resistivity in the range between 2 Ohm cm and 15 Ohm cm, the disclosed technology not being limited thereto.

In block 220 method 200 forms an n⁺ front surface field (FSF) region 11 at the front side of the substrate 10. The FSF may for example be formed by POCl₃ diffusion. Examples of other methods that may be used for forming the FSF are diffusion from a doped dielectric layer or from a doped spin-on or spray-on source or from a dopant containing paste, epitaxial growth, laser doping or ion implantation, the disclosed technology not being limited thereto. In the example shown in FIG. 1 the FSF extends over the entire front surface of the cell. However, the disclosed technology is not limited thereto, and the FSF may for example be a local FSF that may be present only at the location of the front side contacts 17.

In block 230 method 200 removes, in the example wherein the FSF is formed by POCl₃ diffusion, the phosphosilicate glass (PSG) formed during the POCl₃ diffusion step at both sides of the substrate 10 and the n⁺ layer formed at the rear side of the substrate 10 as a result of the POCl₃ diffusion step. The PSG may for example be removed in a HF/HCl solution. The n⁺ layer formed at the rear side may be removed by (single side) silicon etching, for example based on HF/HNO₃ chemistry, the disclosed technology not being limited thereto.

In block 240 method 200 deposits a dielectric layer 12 such as, for example, a silicon oxide layer, a silicon nitride layer, a silicon carbide layer, an oxynitride layer or a titanium oxide layer on the front surface of the substrate, for example, by PECVD, for example with a thickness in the range between 5 nm and 150 nm, for example between 5 nm and 120 nm, for example between 20 nm and 50 nm, the disclosed technology not being limited thereto.

In block 250, method 200 grows a p-doped epitaxial layer (doping concentration for example in the range between 10¹⁸ at/cm³ and 5×10²° at/cm³) on the entire rear surface of the substrate 10, thereby forming a rear side emitter region 13 of the photovoltaic cell. The thickness of the p-doped epitaxial layer 13 may for example be in the range between 10 nm and 5 μm, for example between 10 nm and 2 μm, the disclosed technology not being limited thereto. During this epitaxial growth, the front side dielectric layer 12 not only prohibits epitaxial growth on that side of the substrate but it is also exposed to the elevated temperature during the epitaxial step, thereby improving the surface passivation quality of the dielectric layer and transforming the front side dielectric layer into a high quality passivation layer providing a good surface passivation quality.

The epitaxial growth of block 250 can be followed by the deposition of an antireflection coating (ARC) 15, such as a silicon nitride layer at the front side (block 250 of method 200) and the deposition of a rear side surface passivation layer (block 270 of method 200), for example, comprising depositing an Al₂O₃ passivation layer. In block 280 method 200 deposits an additional rear side dielectric layer, such as a PECVD silicon oxide, silicon nitride, oxynitride or silicon carbide layer, on the rear side surface passivation layer. The stack of the rear side passivation layer and the additional rear side dielectric layer is shown in FIG. 1 as a single layer 14.

In the example shown in FIG. 2, in block 260 method 200 deposits antireflection coating 15 at the front side, after which, in block 270 and block 280, method 200 deposits the rear side passivation layer and the additional rear side dielectric layer, respectively. However, the disclosed technology is not limited thereto and a different process step sequence may be used. For example, method 200 first deposits the rear side passivation layer and the additional rear side dielectric layer in blocks 270 and 280, respectively, and then method 200 deposits antireflection coating 15 at the front side (block 260 of method 200).

In block 290 method 200 forms contact openings by laser ablation or another patterning technique at the front side through the antireflection coating 15 and the font side passivation layer 12, thereby locally exposing the front surface field (FSF) region 11, and at the rear side through dielectric layer stack 14, thereby locally exposing the rear side emitter region 13. After the formation of the contact openings a metallization step is done for providing front side metal contacts 17 to the front surface field region 11 and rear side metal contacts 16 to the rear side emitter region 13.

In the example shown in FIG. 1 and FIG. 2 the dielectric layer 12 is deposited at first predetermined locations, wherein the first predetermined locations correspond to the front surface of the substrate 10. The doped epitaxial layer 13 is grown at second predetermined locations, wherein the second predetermined locations correspond to the rear surface of the substrate 10. Therefore, in this example, the first predetermined locations and the second predetermined locations are located on opposite surfaces of the substrate. If the epitaxial deposition is done in an environment where both substrate surfaces are exposed to the precursors used during epitaxial growth, the dielectric layer 12 at the front side acts as a masking layer for the epitaxial growth.

In the photovoltaic cell the dielectric layer 12 functions as a good front surface passivation layer. This layer can be retained in the photovoltaic device.

Experiments were done wherein n-type Cz—Si test wafers were prepared to test the passivation quality of a PECVD SiOₓ layer (corresponding to dielectric layer 12). Towards this end, a FSF region was formed at both sides of textured wafers, followed by phosphosilicate glass (PSG) removal and deposition of a PECVD SiOₓ layer on both wafer surfaces, to end up with a symmetrical device. Subsequently, the wafers were exposed to the thermal budget corresponding to the epitaxy without any actual epitaxial growth.

Photoluminescence and quasi steady state photo conductance (QSSPC) measurements were used to quantify the passivation quality of the FSF/passivation combination. It was surprisingly found that the approach of the disclosed technology results in very low surface recombination current densities (lower than 10 fA/cm²), lower than recombination current densities obtained for similar test wafers with a combination of a FSF and a thermal oxide as a passivation layer (30-60 fA/cm²). Besides the excellent surface passivation obtained, these improved recombination current densities may also be related to a reduced drive-in of the FSF dopants due to a reduced thermal budget, and thus a stronger field near the wafer surfaces.

Large area (12.5 cm×12.5 cm) n-Si rear junction photovoltaic cells 100 were made according to the method illustrated in FIG. 2 and described above. A first group of cells the rear surface, on which the epitaxial growth occurs, was chemically polished. A second group of cells the rear surface was textured. The front side metallization 17 was done using an integrated Ni/Cu/Ag plating sequence. The rear side dielectric stack 14 consisted of an ALD-Al₂O₃ surface passivation layer thickened by a PECVD SiOₓ layer. The rear side metallization 16 was provided by Al sputtering. The following average characteristics for small cell batches (about 7 cells per group) were measured: an average cell efficiency of 20.0% for the cells with a textured rear surface (second group) and an average cell efficiency of 20.3% for cells with a polished rear surface (first group). For the second group the average short-circuit current density J_{sc} was 38.6 mA/cm², the average open-circuit voltage V_{oc} was 654 mV and the average fill factor FF was 79.1%. For the first group the average J_{sc} was 38.9 mA/cm², the average V₀ 658 mV and the average FF 79.5%.

One advantage of method 200 described above and schematically shown in FIG. 2 that the rear side passivation and the front side passivation can be optimized independently, for example, a good surface passivation layer is formed at the n-doped front side and a different optimized surface passivation layer (such as an Al₂O₃ layer) may be provided at the p-doped rear side. If thermal oxidation would be used for the front side passivation, this would require an additional etching step for removing the thermal oxide from the rear surface.

As illustrated above, using a method according to the disclosed technology, a good surface passivation on one side of the cell can be combined with the creation of an epitaxial emitter on the opposite side of the device with a limited number of steps and with only a single step at high temperature. This avoids the need for any additional masking steps, or dopant activation steps, or additional annealing steps.

A method of the disclosed technology may be used to form a good surface passivation layer at first predetermined locations on a surface of a semiconductor substrate and for forming an epitaxial layer at second predetermined locations on the same surface of the semiconductor substrate, the second predetermined locations being different from and non-overlapping with the first predetermined locations.

An example of a photovoltaic cell 300 that may be fabricated using a method of the disclosed technology, with the first predetermined locations and the second predetermined locations at the same substrate side, is shown in FIG. 3. The cell 300 shown in FIG. 3 is a p-Si PERC-type cell fabricated on a p-type silicon substrate 30. It comprises a local back surface field (B SF) region 33 that is epitaxially grown at second predetermined locations on the rear surface of the substrate 30. The remaining rear side surface is passivated by a low quality APCVD or PECVD SiOₓ layer, transformed during the epitaxial step into a high quality passivating layer 34. The cell 300 further comprises at the front side an emitter region 31, a front surface passivation layer 32, an antireflective coating 35 and a front side contact 37. At the rear side a rear side contact 36 is provided.

A method for fabricating the photovoltaic cell 300 of FIG. 3 in accordance with a method 400 of the disclosed technology is schematically shown in FIG. 4.

In block 410, method 400 textures the front surface of a silicon substrate 30, for example by etching in a KOH solution, a NaOH solution, a TMAH solution, a HF/HNO₃/CH₃COOH solution or by plasma texturing. The texturing may be a single side texturing step, wherein the rear side may be masked during texturing, or it may be a double side texturing step without masking. In the latter case the texturing may be followed by a rear surface polishing step. In the example described here, the silicon substrate 30 is an p-type crystalline silicon substrate, for example with a resistivity in the range between 0.2 Ohm cm and 10 Ohm cm, the disclosed technology not being limited thereto.

In block 420, method 400 forms an n-type emitter region 31 at the front side of the substrate 30. The emitter region 31 may for example be formed by POCl₃ diffusion. Examples of other methods that may be used for forming the emitter region are diffusion from a doped dielectric layer or from a doped spin-on or spray-on source or from a dopant containing paste, epitaxial growth, laser doping or ion implantation, the disclosed technology not being limited thereto.

In block 430, method 400 removes the phosphosilicate glass (PSG) formed during the POCl₃ diffusion step at both sides of the substrate 30 and the n⁺ layer formed at the rear side of the substrate 30 as a result of the POCl₃ diffusion step. The PSG may be removed in a HF/HCl solution. The n⁺ layer formed at the rear side may be removed by (single side) silicon etching, for example based on HF/HNO₃ chemistry, the disclosed technology not being limited thereto.

In block 440, method 400 provides a surface passivation layer 32 such as a silicon oxide layer is provided on the front surface of the substrate, for example with a thickness in the range between 5 nm and 200 nm, for example between 5 nm and 120 nm, for example between 20 nm and 50 nm, the disclosed technology not being limited thereto. In embodiments of the disclosed technology, the front side surface passivation layer 32 may be a thermal oxide layer. In other embodiments, the front side surface passivation layer 32 may be a deposited silicon oxide layer, for example a PECVD silicon oxide layer, wherein the surface passivation quality of this layer is improved during the epitaxial growth further in the process sequence.

In block 450, method 400 deposits a dielectric layer 34 such as a silicon oxide layer, a silicon nitride layer, a silicon carbide layer, an oxynitride layer or a titanium oxide layer on the rear surface of the substrate 30, for example by PECVD, for example with a thickness in the range between 40 nm and 500 nm, e.g. between 75 nm and 200 nm, the disclosed technology not being limited thereto. This is followed in block 460, by method 400, by rear contact opening, for example by laser ablation, resulting in a patterned dielectric layer 34 at first predetermined locations, with openings at the locations (second predetermined locations) where a BSF region is to be formed.

In block 470 method 400 grows a p⁺-doped epitaxial layer (doping concentration for example in the range between 10¹⁸ at/cm³ and 5.10²⁰ at/cm³) on the rear surface of the substrate 30, thereby using the patterned dielectric layer 34 as a mask and forming local B SF regions 33. The thickness of the p^{t}-doped epitaxial layer 33 may be in the range between 10 nm and 5 μm, such as between 50 nm and 3 μm, the disclosed technology not being limited thereto. During this epitaxial growth, the rear side dielectric layer 34 not only prohibits epitaxial growth at the first predetermined locations but it is also exposed to the elevated temperature during the epitaxial step, thereby transforming the rear side dielectric layer 34 into a high quality dielectric layer providing a good surface passivation quality. Epitaxial growth at the front side is prohibited by the front side surface passivation layer 32 provided in step 23. In embodiments wherein the front side surface passivation layer 32 is a deposited layer, such as a PECVD SiOₓ layer (similar to layer 34), the elevated temperature to which it is exposed during the epitaxial growth step may improve the surface passivation quality of this PECVD SiOₓ layer 32.

Method 400 follows epitaxial growth of block 470 by depositing, in block 480, an antireflection coating (ARC) 35, such as a silicon nitride layer, at the front side. In block 490 method 400 forms contact openings by laser ablation or another patterning technique at the front side, followed by a metallization step to provide front side metal contacts 37 to the emitter region 31 and rear side metal contacts 36 to the rear side BSF regions 33.

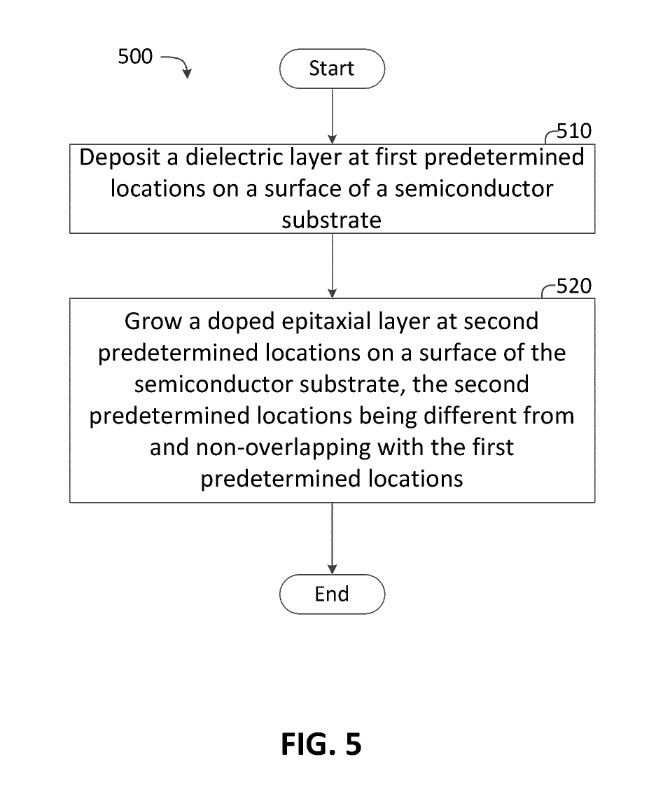

FIG. 5 is a flowchart illustrating an embodiment of a method 500 for fabricating a crystalline semiconductor photovoltaic cell in an embodiment of the disclosed technology. In block 510, method 500 deposits a dielectric layer at first predetermined locations on a surface of a semiconductor substrate. In block 520, method 50 grows a doped epitaxial layer at second predetermined locations on a surface of the semiconductor substrate, the second predetermined locations being different from and non-overlapping with the first predetermined locations. The dielectric layer remains on the surface of the semiconductor substrate during fabrication of the photovoltaic cell. The dielectric layer is maintained as a surface passivation layer of the photovoltaic cell.

The foregoing description details certain embodiments of the disclosure. It will be appreciated, however, that no matter how detailed the foregoing appears in text, the disclosure may be practiced in many ways. It should be noted that the use of particular terminology when describing certain features or aspects of the disclosure should not be taken to imply that the terminology is being re-defined herein to be restricted to including any specific characteristics of the features or aspects of the disclosure with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the invention.

What is claimed is:

1. A method for fabricating a crystalline semiconductor photovoltaic cell, the method comprising:
depositing a dielectric layer at first predetermined locations on a surface of a semiconductor substrate; and
growing a doped epitaxial layer at second predetermined locations on a surface of the semiconductor substrate, the second predetermined locations being different from and non-overlapping with the first predetermined locations,
wherein the dielectric layer remains on the surface of the semiconductor substrate during fabrication of the photovoltaic cell, and wherein the dielectric layer is maintained as a surface passivation layer of the photovoltaic cell.

2. The method of claim 1, wherein the dielectric layer is deposited at a temperature lower than 500° C.

3. The method of claim 1, wherein depositing the dielectric layer at the first predetermined locations comprises depositing the dielectric layer by chemical vapor deposition, atomic layer deposition, pyrolytic coating, spin coating, spray coating or dip coating.

4. The method of claim 1, wherein the dielectric layer comprises silicon oxide, silicon nitride, silicon carbide, oxynitride or titanium oxide.

5. The method of claim 1, wherein growing the doped epitaxial layer comprises growing the doped epitaxial layer at a temperature in the range between 600° C. and 1000° C.

6. The method of claim 1, wherein the doped epitaxial layer forms an emitter region, a back surface field region and/or a front surface field region of the photovoltaic cell.

7. The method of claim 1, wherein the first predetermined locations and the second predetermined locations are present on a same surface of the semiconductor substrate.

8. The method of claim 1, wherein the first predetermined locations and the second predetermined locations are present on opposite surfaces of the semiconductor substrate.

9. The method of claim 1, wherein the first predetermined locations are present on both surfaces of the semiconductor substrate.

10. The method of claim 1, wherein the second predetermined locations are present on both surfaces of the semiconductor substrate.

11. The method according to claim 1, wherein depositing the dielectric layer at the first predetermined locations comprises depositing the dielectric layer at the first predetermined locations and at the second predetermined locations, followed by removing the dielectric layer from the second predetermined locations.

12. The method according to claim 1, wherein growing the doped epitaxial layer at the second predetermined locations comprises exposing both surfaces of the semiconductor substrate surfaces to a precursor, the precursor used during epitaxial growth.
